(19) United States
(12) Patent Application Publication
(10) Pub. No.: US 2021/0335435 A1
(43) Pub. Date: Oct. 28, 2021

(54) JTAG BASED ARCHITECTURE ALLOWING MULTI-CORE OPERATION

(71) Applicant: Micron Technology, Inc., Boise, ID (US)

(72) Inventors: Alberto Troia, Munich (DE); Antonino Mondello, Messina (IT)

(21) Appl. No.: 16/625,479

(22) PCT Filed: May 31, 2019
(86) PCT No.: PCT/IB2019/000485

§ 371 Date: Dec. 20, 2019

(51) Int. Cl. G11C 29/16; G11C 29/32; G11C 7/06; G11C 7/10; H03K 19/173

(52) U.S. Cl. CPC G11C 29/16; G11C 29/32; G11C 7/06; G11C 7/106; G11C 2029/3202; G11C 7/1057; G11C 7/1084; H03K 19/1737; G11C 7/1087

(57) ABSTRACT

The present disclosure relates to an apparatus comprising:

a memory component having an independent structure and including at least an array of memory cells with associated decoding and sensing circuitry and a memory controller;

a host device including multiple cores and coupled to the memory component through at least a communication channel for each corresponding core;

a control and JTAG interface in said at least an array of memory cells;

at least an additional register in said control and JTAG interface for handing data, addresses and control signals provided by the host device and to be delivered to said decoding circuitry and to said controller to perform modify operations.

### TECHNICAL FIELD

The present disclosure relates generally to memory devices, and more particularly, to apparatuses and methods for non-volatile memory management. More particularly, the present disclosure relates to a JTAG based architecture allowing multi-core operation in a non-volatile memory device.

### BACKGROUND

Non-volatile memory can provide persistent data by retaining stored data when not powered and can include different topology of memory components. For instance, NAND flash memories and NOR flash memories may be considered equivalent circuits in terms of cells interconnections and reading structure, even if their performances are different.

A memory circuit having a NAND or NOR configuration may be realized adopting different technologies, for instance: floating gate (FG), charge-trapping (CT), phase change random access memory (PCRAM), self-selecting chalcogenide-based memories, resistive random access memory (RRAM), 3D XPoint memory (3DXP) and magnetoresistive random access memory (MRAM), among others.

Non-volatile Flash memories are today one of the fundamental building blocks in modern electronic systems, particularly for Real Time Operating Systems (RTOS), since they store code, firmware, O.S., applications and other software. The operation of non-volatile Flash memories is managed by an internal controller including an embedded firmware, such controller performing the required write/read/erase operations by manipulating the voltages and timing on the access and data lines.

The performances of Flash memories in terms of speed, consumption, alterability, nonvolatility and the increasing importance of system reconfigurability have pushed for their integration in System-on-Chip (SoC) devices. However, there are several non-volatile technologies used in SoC but the programming methodologies are requiring more space and the software is complicated in comparison to the past to full fill new regulations. This drawback is pushing toward the search of having more storage space with difficulties in integrating such a storage space in a SoC.

Moreover, embedded memory in System on Chips is more and more difficult to be managed when the lithography node is below 28 nm.

Therefore, there is a need for providing a new interface architecture that can be easily integrated in a SoC and improves the performances of the non-volatile memory portion while having a low initial latency in the first access and improving the overall throughput.

### BRIEF DESCRIPTION OF THE DRAWINGS

FIG. 1 shows a schematic view of a host device, for instance a System-on-Chip, coupled to a non-volatile memory component according to embodiments of the present disclosure;

FIG. 2 is a schematic view of the internal layout of a memory portion of FIG. 1 according to one embodiment of the present disclosure;

FIG. 3 shows a schematic view of a portion of the non-volatile memory component of FIG. 1 including a layout configuration according to the present disclosure;

FIG. 4A is a schematic view of a particular of the memory portion shown in FIG. 2;

FIG. 4B is a schematic view of the connections between a generic memory cell and a corresponding sense amplifier with the inclusion of the modified JTAG cell according to the present disclosure;

FIG. 4C is a schematic view of memory block formed by a plurality of rows of a memory array according to one embodiment of the present disclosure;

FIG. 5 is a schematic view of JTAG cell that has been modified according to the present disclosure;

FIG. 6 shows a schematic view of a standard structure architecture using boundary-scan cell configured according to the IEEE standard No. 1149.1 but including the modified JTAG cells of FIG. 5;

FIG. 7 is a diagram showing schematically in greater details the composition of registers incorporated into a boundary-scan architecture of the present disclosure;

FIG. 8 shows a diagram reporting the operations of a Finite State Machine based on the JTAG protocol

### DETAILED DESCRIPTION

With reference to those figures, apparatuses and methods involving a non-volatile memory device 1 or component and a host device 10 for such a memory device will be disclosed herein.

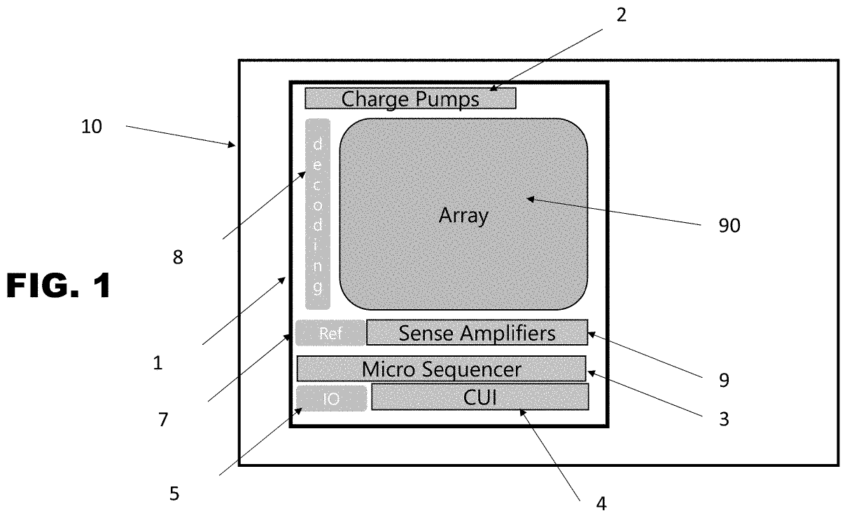

The host device 10 shown in FIG. 1 can be a System-on-Chip with an embedded memory component 1 or a more complex electronic device including a system coupled to a memory device, as will appear from the description of other embodiments of the present disclosure made with reference to other figures. In any case, the System-on-Chip 10 and the memory device 1 are realized on a respective die obtained by a different lithography process.

As an alternative, the system 10 may be an external controller in communication with the System-on-Chip but for the purpose of the present disclosure we will refer to the host device or to the SoC as entities in communication with the memory component.

For instance, the system 10 can be one of a number of electronic devices capable of using memories for the temporary or persistent storage of information. For example, a host device can be a computing device, a mobile phone, a tablet or the central processing unit of an autonomous vehicle.

More specifically, modern embedded systems use some type of flash memory devices for non-volatile storage. Embedded systems use memories for a range of tasks, such as the storage of software code and lookup tables (LUTs) for hardware accelerators.

The present disclosure suggests improving the memory size by providing a structurally independent memory component 1 coupled to the host device 10 or System-on-Chip. The memory component 1 is structured as a stand-alone device realized in a single die with a technology specifically dedicated to the manufacturing of flash memory devices. The memory component 1 is an independent structure but it is strictly associated to the host device or to the SoC structure. More particularly, the memory device 1 is associated and linked to the SoC structure partially overlapping such a structure while the corresponding semiconductor area of the SoC structure has been used for other logic circuits and for providing support for the partially overlapping structurally independent memory device 1 for instance through a plurality of pillars, through silicon vias (TSV), or other similar alternative connections such as ball on grid or with a technology similar to Flip-Chip.

The final configuration will be a face-to-face interconnection SoC/Flash Array with the sense amplifiers will be connected to the SoC in a Direct Memory Access configuration. In this manner it is possible to keep relatively low the number of required interconnections, in particular within the range of about 600 to 650 pads.

More specifically, this non-volatile memory component 1 includes an array 90 of Flash memory cells and a circuitry located around the memory array. The coupling between the SoC structure 10 and the memory component 1 is obtained by interconnecting a plurality of respective pads or pin terminals that are faced one toward the other in a circuit layout that keeps the alignment of the pads even if the size of the memory component is modified.

In one embodiment of the present disclosure, the arrangement of the pads of the memory component has been realized on a surface of the memory component 1, in practice on the top of the array. More specifically, the pads are arranged over the array so that, when the memory component 1 is reversed, its pads are faced to corresponding pads of the host or SoC structure 10.

At the end, the memory device 1 is manufactured according to the user's needs in a range of capacity values that may vary according to the available technology, for instance from at least 128 Mbit to 512 Mbit or even more without any limitation for the applicant's rights. More specifically, the proposed external architecture allows to overpass the limit of the current eFlash (i.e. embedded flash technology) allowing the integration of bigger memory, as it can be 512 Mbit and/or 1 Gbit and/or more depending on the memory technology and technology node.

More particularly, the Flash memory component 1 includes an I/O circuit 5, a micro-sequencer 3 and sense amplifiers 9.

The Flash memory component 1 further includes a command user interface CUI 4, voltage and current reference generators 7, charge pumps 2 and decoding circuitry 8 located at the array periphery.

To read the memory cells of the Array 90 it is provided a dedicated circuit portion including an optimized Read Finite State Machine that is used to ensure high read performance, such as: branch prediction, fetch/pre-fetch, interrupt management. The error correction is left to the SoC 10; additional bits are provided to the memory controller to store any possible ECC syndrome associated with the page. The ECC allow the host also to correct the received data. The host is responsible to fix the data in the memory based on the correction made in the received data cells.

All in all, the Flash memory component 1 of the present disclosure comprises: the memory array, a micro sequencer, a control and JTAG logic, sense amplifiers and corresponding latches.

This Flash memory component 1 uses the interconnection pads of the array and logic circuit portion to allow the interconnection with the host or SoC structure 10.

The final configuration will be a face-to-face interconnection SoC/Flash Array, wherein the sense amplifiers 9 of the memory component 1 will be connected to the SoC in a Direct Memory Access configuration for user mode high frequency access.

The Direct Memory Access allows to reduce the final latency that the SoC can experience when reading the data. Moreover, the final latency is also reduced by the block form factor, the sense amplifiers distribution between blocks, the selection of the comparison threshold in the sense amplifiers and the optimized path.

The interconnections also include JTAG interface 300 and control pins for testing and other purposes. The core of the SoC device 10 can have access to the JTAG interface 300 with high speed pads that are used in the fast read path versus the SoC, while a low speed path is dedicated to the testing phase. The JTAG cells are part of the fast path, but the JTAG interface is using the slower path.

Embodiments of the present disclosure relates to an apparatus comprising:
a memory component having an independent structure and including at least an array of memory cells with associated decoding and sensing circuitry and a memory controller;
a host device including multiple cores and coupled to the memory component through at least a communication channel for each corresponding core;
a control and JTAG interface in said at least an array of memory cells;
at least an additional register in said control and JTAG interface for handing data, addresses and control signals provided by the host device and to be delivered to said decoding circuitry and to said controller to perform modify operations.

The apparatus of the present disclosure is structured to include a plurality of sub arrays and said additional register in said control and JTAG interface supports data and address registers of said plurality of sub arrays of memory cells.

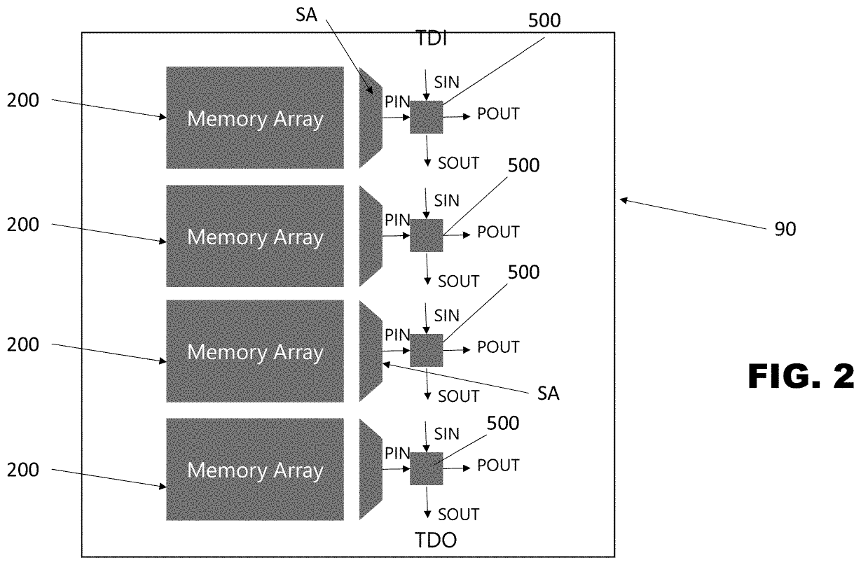

Coming now to a closer look to the internal structure of the memory component 1 it should be noted that the architecture of the array 90 is built as a collection of sub arrays 200, as shown schematically in FIG. 2.

Each sub array 200 is independently addressable inside the memory device 1. Each sub-array 200 contains multiple memory blocks 160.

In this manner, having smaller sectors if compared to known solutions the access time is significantly reduced and the whole throughput of the memory component is improved. The reduction of the initial latency time is at block level because the row and column lines, the read path associated latency and the external communication have been optimized.

In the embodiments disclosed herewith the memory array 90 is structured with a number of sub-arrays 200 at least corresponding to the number of cores of the associated SoC 10 and, therefore to the number of corresponding communication channels. For instance, at least four memory sub arrays 200 one for each communication channel with a corresponding core of the SoC 10 are provided.

The host device or the System-on-Chip 10 normally includes more than one core and each core is coupled to a corresponding bus or channel for receiving and transferring data to the memory component 1.

Therefore, in the present implementation each sub-array 200 has access to a corresponding channel to communicate with a corresponding core of the System-on-Chip 10. The outcome of the memory blocks is driven directly to the SoC without using high power output buffers and optimizing the path.

The advantage of this architecture is that it is very scalable, wherein expanding and/or reducing the density of the final device translates only in mirroring a sub-array and generating the connection or increasing the number of blocks of each subarray, that is the available density per core.

In embodiments of the present disclosure each independently addressable location of the blocks of each memory sub array 200 addresses an extended page 150 that will be named defined hereinafter with the term super page.

As non-limiting example, this extended page 150 comprises a string including a first group of at least one-hundred-twenty-eight (128) Bit for the I/O data exchange with the SoC device 10 plus at least a second group of twenty-four (24) address Bit and a final or third group of at least sixteen (16) ECC Bit. The twenty-four (24) address Bit are sufficient to address up to 2 GigaBit of available memory space.

According to the present disclosure, the outputs of the sense amplifiers SA prepare a double extended page at a time, i.e. a super-page 150 comprising a number of Bits given by the double combination of the above-mentioned three groups of data bits, address bits and ECC bits, according to the size of the memory array.

In the specific but non-limiting example disclosed herewith each extended page 150 includes at least 168 Bit obtained by the combination of the above three groups of 128+24+16 data, address and ECC Bit and each super-page is formed by a couple of extended pages, i.e. a group of 168×2 Bits.

Just to give a non-limiting numeric example, each row of a memory block includes sixteen extended pages. Therefore, the resulting row includes 2688 Bit coming out from the combination of sixteen extended pages independently addressable and each including 168 Bit or, said differently, the combination of eight super-pages.

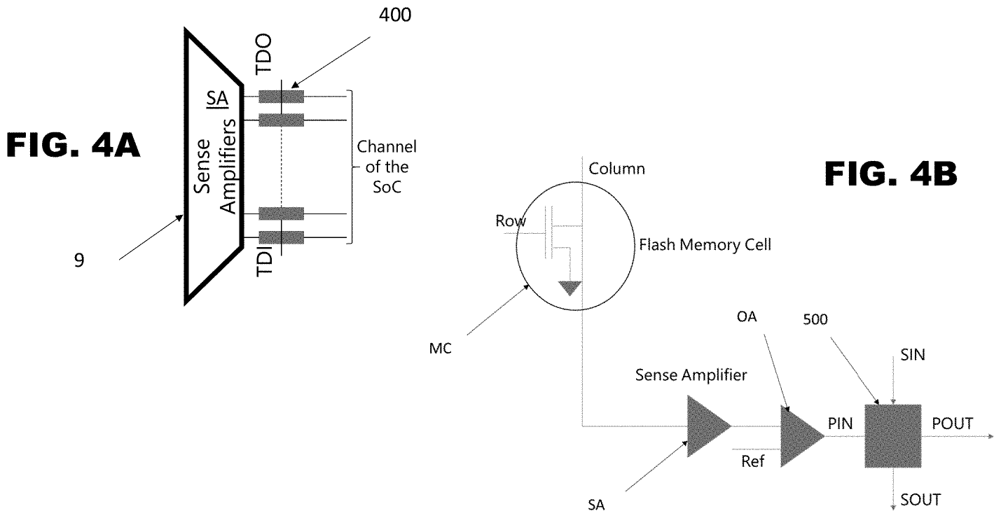

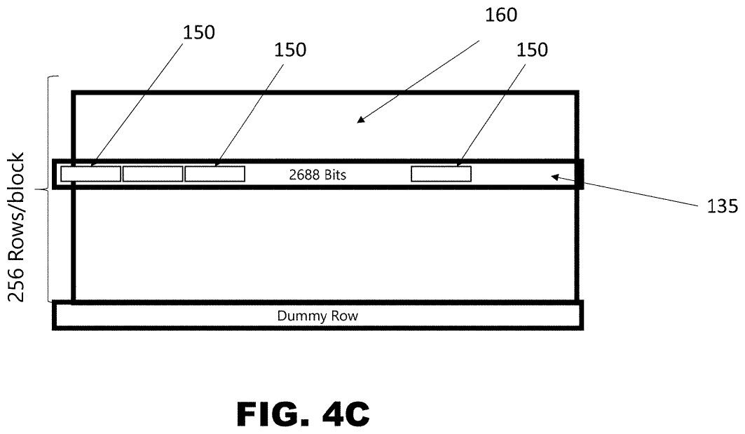

In embodiments of the present disclosure the output of a generic sub-array 200 is formed combining the following sequence: data cells plus address cells plus ECC cells. In this non-limiting example the total amount of Bits would involve 168 pads per channel, as shown in FIG. 4A.

The combined string of data cells+address cells+ECC cells allows implementing the whole safety coverage of the bus according to the standard requirements, because the ECC covers the whole bus communication (data cells+address cells), while the presence of the address cells provide the confidence that the data is coming exactly from the addressed location of the controller.

The sense amplifiers SA of each sub array 120 are connected with a scan-chain of modified JTAG cells 500, connecting together all the output of one sub-array 200. Moreover, the modified JTAG cells 500 associated to a sub array 200 can be interconnected to form a unique chain 400 for quickly checking the integrity of the pads interconnections.

Thanks to the memory architecture of the present disclosure it is possible to pass from a parallel mode for retrieving data and addresses from the memory sub arrays 200 to a serial mode for checking the interconnections between the memory component 1 and the associated SoC device 10. Moreover, the SoC is entitled to read once ‘1’ and once ‘0’ to perform tests and can also analyze the memory outcome, scanning out the data using the scan-chain.

It should be further noted that each subarray 200 includes address registers connected to data buffer registers, similarly to an architecture used in a DRAM memory device, i.e. DDRX type of DRAMs.

In the following paragraphs of the present disclosure it will be apparent that the outputs of the sense amplifiers SA per sub array 200 are latched by an internal circuit, so to allow to the sense amplifiers to execute a further internal read operation to prepare the second nibble or group of 128 Bits. This second nibble is transferred to the output of the flash array 90, using an additional enabling signal (i.e. an internal clock signal or an ADV signal) that transfers the content read at sense amplifier level to the host device or SoC device 10.

In other words, the internal sense amplifiers prepare two extended pages 150 and while the first page is ready to be shifted, internally it is performed a reading phase of the second page associated with the same address. This allows to prepare from five to eight double word (in the present example), that are typical in the RTOS application. In any case, the disclosed structure can be expanded to allow multi-page read while shifting out the already read page.

The sense amplifiers SA are connected directly to a modified JTAG cells 500, that will be later disclosed, so to integrate a JTAG structure and the sense amplifiers in a single circuit portion. This allows reducing as much as possible the delay in propagating the output of the memory array to the SoC.

Just to report a numeric example based on the embodiment disclosed herewith, we may remark that each address in the address buffers is linked to a data buffer, containing for instance 128 Bits. However, the SoC can need up to 256 Bits at a time, so the data buffers will be duplicated so to be able to shift, assuming to use the address 0 of the sub array 0:

First pass of the first group of Bits: Data 0_0_H [127:0]

Second pass of the second group of Bits: Data _0_L [127:0]

In one embodiment the address buffers are realized making use of modified JTAG cells as we will see hereinafter.

In one embodiment of the present disclosure each sub array 200 is independently addressable inside the memory device 1.

Each block 160 of each memory sub array 200 is structured with a row 135 containing at least 16 double words of 32 bits each, plus the address and ECC syndrome spare bits per page with memory word of thirty-two (32) Bits. This architecture is similar to a DRAM like scheme for preparing multiple addresses at the same time. For instance, each address may include 128 Bits plus 128 Bits to form the super page previously mentioned.

A skilled in this art may appreciate that a larger or a smaller memory device can be structured with an increased number of memory sub arrays 200 thus expanding or reducing the density of the final memory device 1. A larger memory device is obtained for instance by mirroring a sub array 200 and providing the corresponding interconnections in a very scalable manner.

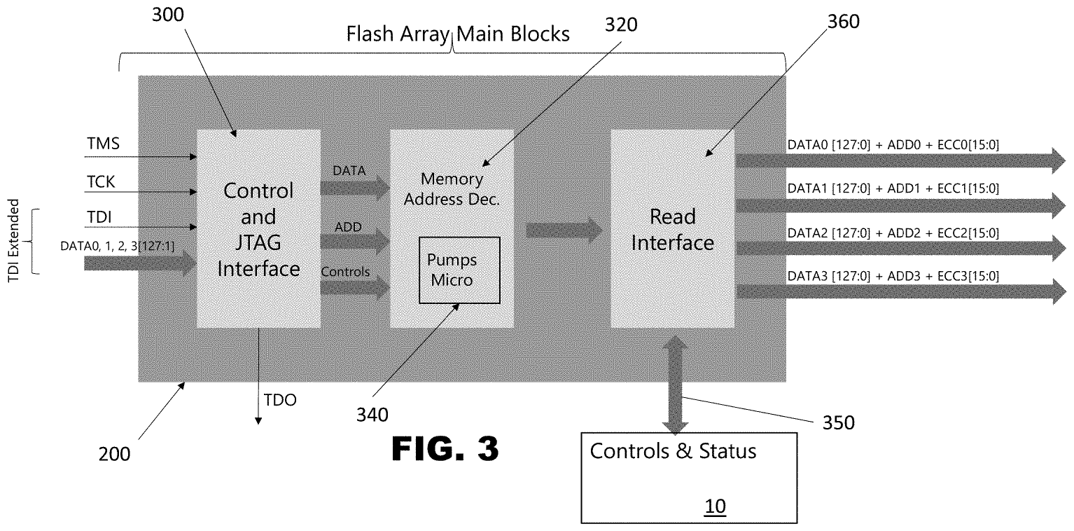

FIG. 3 shows a schematic view of the main components of the non-volatile memory component 1 of the present disclosure.

According to the previous disclosure, the memory component 1 is realized in a so-called Known Good Die or Bare Die form factor or in a bare die form and presents all the sub-array portions with corresponding sense amplifiers SA outputs connected directly with the host controller, except for a latch structure in the middle.

Strategies for obtaining the KGD form factor have been based on a JTAG interface 300 that allows the re-use of the testing tooling. The adopted method minimizes the amount of hardware, tooling, or insertions that add cost to the bare die products since that the functionality is tested in a low cost environment, ie. wafer fab facility.

This approach has led to the development of KGD carriers, wafer-level burn-in, and high-performance hot-chuck probing—all focused on being effective for testing and reliability screening of infant mortalities.

In more details, each sub-array 200 includes at least a control and JTAG interface 300 receiving as inputs standard JTAG signals: TMS, TCK, TDI as well as data from a memory page of 128 Bits. These data and the TDI signal may be considered an extended TDI that is also a flexible TDI. The flexibility is due to the fact that the number of parallel bits working as TDI are depending from the selected registers, i.e. four lines for the instruction register, eight lines for the address register, 128 lines for the data register, etc. while TDI comes from the JTAG protocol that uses TDI as name on the signal used to fill the registers.

This control and JTAG interface 300 produces as output data, addresses and control signals that are transferred to a memory address decoder 320 and also to the internal flash controller to perform modify operations.

The activity of the decoder is allowed by charge pumps 340 structured to keep secret the voltages and timings to manage the array.

This decoder 320 is coupled to a read interface 360 that is in communication with the host or SoC device 10 through a control and status bus 350.

The output of the read interface 360 is represented by the extended page including the combined string of data cells +address cells +ECC cells.

The total amount of Bits would involve in the example disclosed herewith one-hundred-sixty-eight pads per channel in the implementation disclosed herewith.

The combined string of data cells +address cells +ECC cells forming the extended or super page 150, shown schematically in FIG. 4C, allows implementing the whole safety coverage of the bus according to the standard requirements of the rule ISO26262, because the ECC covers the whole bus communication (data cells+address cells), while the presence of the address cells provides the confidence that the data is coming exactly from the addressed location of the controller, i.e. if ADD==ADD0.

The ECC cells allows the host controller to understand if corruption is happening in the data plus address content.

The implementation of this mechanisms ensures the optimization of the read operation of the memory.

FIG. 4A shows a schematic view of a memory portion wherein the subarray 200 architecture is structured to serve at least a channel of the SoC structure 10 to which the memory component 1 is associated.

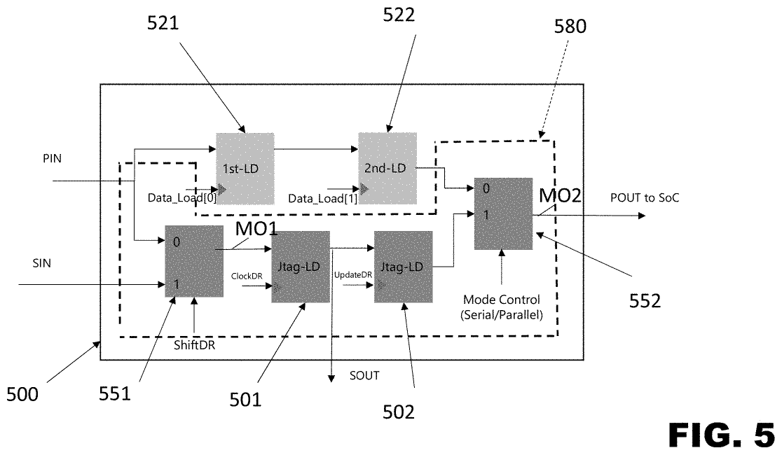

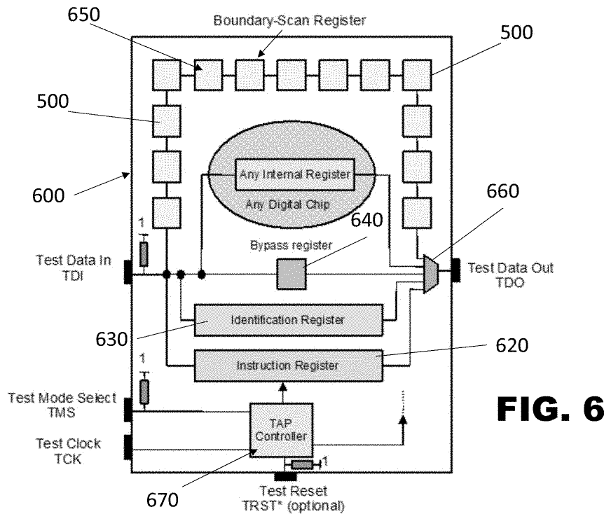

The sense amplifiers SA are connected directly to a modified JTAG cells 500, that will be later disclosed with reference to FIG. 5, so to integrate a JTAG structure and the sense amplifiers in a single circuit portion. This allows reducing as much as possible the delay in propagating the output of the memory array to the SoC.

The sense amplifiers SA of each sub array 200 are connected with the scan-chain 400 of modified JTAG cells 500, connecting together all the output of one sub-array 200. Moreover, the sub array scan-chains 400 can be connected to form a unique chain for quickly checking the integrity of the pads interconnections.

The JTAG Cell 500 is connected in the following manner shown in FIG. 4B:

PIN→output of a sense amplifier

POUT→to the SoC correspondent Data I/O

SIN→is the serial IN input connected to the SOUT of the previous sense amplifier

SOUT→is the serial output connected to the SIN of the next sense amplifiers

The scan chain 400 made by the interconnected JTAG cells 500, using the serial input and output, has some advantages:
be able to test the successful interconnection between the SoC and the Direct Memory Access (DMA) Memory;
be able to implement digital test of the sense amplifiers, because the cell can work as program load to store the data inside the array;
be able to work as second level of latches.

We will see later in the present disclosure that when the first group of data Bits are ready to be transferred to the parallel output POUT of the sense amplifier, there is an internal latch coupled to the sense amplifier that can trigger the read data of the subsequent section of the remaining data Bits.

Still making reference to the examples of the FIGS. 4A and 4B we may consider the interconnections of each JTAG Cell 500: PIN is coupled to the output of a sense amplifier; POUT is coupled to the corresponding Data I/O of the host device 10 (i.e. the System-on-Chip); SIN is the serial IN input connected to the SOUT of the previous sense amplifier while SOUT is the serial output connected to the SIN of the next sense amplifier.

For instance, the schematic example of FIG. 4B shows a schematic and generic memory cell MC which is located at the intersection of a row of memory cells and a column of memory cells in a matrix of cells of a generic sub-array, so that the cell can be addressed accordingly. The real implementation can contain additional circuits from the cell to the output of the SA but they are not shown not being relevant for the purpose of the present disclosure.

A sense amplifier SA is coupled to the column of memory cells as part of the read circuitry that is used when a data is read from the memory array. Generally speaking a memory word including the above-mentioned super page 150 is read at a time and in the present example we will make reference to a memory word including data+address+ECC Bits.

As is well known, the role of the sense amplifier is that of sensing the low power signals from the array row. The low voltage values representing the logic data Bit (1 or 0, depending on conventions) stored in the memory cell MC are amplified to a recognizable logic level so the data can be properly interpreted by logic circuit portions outside the memory.

In the example disclosed herewith the output of each sense amplifier SA is coupled to the modified JTAG cell 500 so to integrate a JTAG structure and the sense amplifier.

In the non-limiting example disclosed herewith an output amplifier OA is interposed between the sense amplifier SA and the JTAG cell 500.

Thanks to the memory architecture of the present disclosure it is possible to pass from a parallel mode for retrieving data and addresses from the memory sub arrays 200 to a serial mode for checking the interconnections between the memory component 1 and the associated host device 10. Moreover, the SoC is entitled read once ‘1’ and once ‘0’ to perform tests and can also analyze the memory outcome, scanning out the data using the scan-chain

The passage from the parallel to the serial mode is managed by the control and JTAG interface 300. However, the implementation of these dual mode operations is allowed by the specific structure of a modified JTAG cell 500 disclosed hereinafter.

Making reference to the schematic example of FIG. 5 it is shown a JTAG cell 500 modified according to the present disclosure.

The JTAG cell 500 has a first parallel input PIN terminal and a first serial input SIN terminal receiving corresponding signals Pin and Sin. Moreover, the JTAG cell 500 has a first parallel output terminal POUT and a first serial output terminal SOUT. The scan-chain 400 allows outputting the whole 256 bits, because the first group is read directly from the output while the second group is prepared in the back.

As shown in FIG. 5 the JTAG cell 500 may be considered a box with two input terminals PIN and SIN and two output terminals POUT and SOUT. The input terminal PIN is a parallel input while the input terminal SIN is a serial input. Similarly, the output terminal POUT is a parallel output while the output terminal SOUT is a serial output.

Thanks to the serial input and output a testing process may be performed to check that no fault connection is present between the memory component 1 and the associated System-on-chip 10. Thanks to the parallel input and output the same JTAG cell is used as data buffer for the completing the reading phase through the sense amplifiers SA.

The JTAG cell 500 comprises a boundary scan basic cell 580 including a couple of latches 501 and 502 and a couple of multiplexer 551 and 552. A first input multiplexer 551 and a second output multiplexer 552.

The boundary scan basic cell 580 is indicated by the dotted line box in FIG. 5 and is a two inputs cell, with a serial input corresponding to SIN and parallel input corresponding to PIN, and two outputs cell with a serial output corresponding to SOUT and a parallel output corresponding to POUT.

The first multiplexer 551 receives on a first input “0” a parallel input signal Pin from the first parallel input terminal PIN and on a second input “1” a serial input signal Sin from the first serial input terminal SIN.

This first multiplexer 551 is driven by a control signal ShiftDR and has an output MO1. The cell 500 has two parallel outputs, i.e. MO1 and MO2. When the JTAG clock arrives, the serial output is driven out from the SOUT. SOUT is connected to the JTAG latch close to the multiplexer that receives a selector signal: Mode Controller (serial/parallel). Basically, the output of the latch connected to the input ‘1’ of this multiplexer MO2 is also the SOUT.

The first multiplexer output MO1 is connected to a first input of the first latch 501 that receives on a second input terminal a clock signal ClockDR.

The first latch 501 is connected in chain to the second latch 502 with a first output of the first latch 501 connected to a first input of the second latch 502.

It is important to note that the output of the first latch 501 is also the serial output SOUT of the whole JTAG cell 500.

A second input terminal of the second latch 502 received a signal UpdateDR.

The second latch 502 has an output connected to an input of the second multiplexer 552, in particular to its second input.

This second multiplexer 552 is controlled by a Mode Control signal that allows to switch the whole JTAG cell 500 from a serial to a parallel mode and viceversa.

In one embodiment of the present disclosure the JTAG cell 500 further includes another couple of latches 521 and 522 provided between the parallel input Pin and the second multiplexer 552. These extra latches 521 and 522 are the latching of the direct read, i.e. first group of data Bits, and the shadow one, i.e. second group of 128 data Bits. In other words, the JTAG cell 500 includes the boundary scan cell 580 and at least the further latches 521 and 522.

We will refer hereinafter to these further latches as a third latch 521 and a fourth latch 522. In other embodiments a longer chain of latches may be used.

More particularly, the third latch 521 and the fourth latch 522 are connected in a small pipeline configuration with the third latch 521 receiving on a first input the parallel input signal Pin from the first parallel input terminal PIN and receiving on a second input a signal Data_Load[0] corresponding to a first data load.

The fourth latch 522 receives on a first input the output of the third latch 521 and receives on a second input a signal Data_Load[1] corresponding to a subsequent data load.

The output of the fourth latch 522 is connected to the first input “0” of the second multiplexer 552 that produces on its output terminal MO2 the output signal for the parallel output terminal POUT.

If compared to a conventional JTAG cell the JTAG cell 500 of the present disclosure may be considered a modified JTAG cell because of the presence of the two extra latches, the third and fourth latches 521 and 522, beside the presence of the boundary scan cell 580.

Now, we have to imagine that a JTAG cell 500 is coupled to the output of each sense amplifier SA of the memory sub-array 200. As usual, the memory array provides for a sense amplifier for each column of memory cells, as shown in FIG. 4B.

In the embodiment of the present disclosure all the JTAG cells 500 coupled to the sense amplifiers of a memory sub-array are to be considered a data buffer including a data page, including in this example at least one-hundred-and-twenty-eight (128) Bits for the reading of a combined memory page at a time from the four sub arrays 200.

However, as previously reported, the communication channel between the memory component and the SoC structure may need up to 256 Bits at a time (i.e. two combined memory words) and the JTAG cell 500 has been modified just to duplicate the internal latches to be able to shift the first or higher portion of the 128 Bits of the data to be read with the second or lower portion of the data to be read. Obviously, in this contest “higher” means the data portion that is loaded before while “lower” means the data portion that is loaded after.

A skilled in this art will understand that the number of internal latches of the modified JTAG cell 500 can be augmented in case of need to improve the number of Bits to be transferred to the SoC structure through the communication channel. For example, the above structure may be expanded accordingly to the size of the page required by the particular implementation of the memory controller.

Just to explain the manner in which data are transferred in the data buffer we have to imagine that when a data is loaded in the one of the two latches 521 or 522, the other latch is in a stand-by state but ready to receive the subsequent data portion.

Therefore, the first section including 128 Bit is transferred to the SoC structure for a first data elaboration while the reading phase is not stopped since the other portion of 128 Bits are prepared to be loaded into the latches at the subsequent clock signal.

In this example, each data buffers contains 128 modified JTAG cells 500 and the common Data_Load[1:0] are signals generated to allow to capture the whole 256 Bits, that is to say: eight double words DWs according to the proposed implementation (four sub arrays for each double word).

The signal generation is internally controlled when the read operation is performed in a specific data buffer and the signals are controlled by the SoC structure to allow performing read phase using a 128 Bits parallelism.

The main benefit of this memory architecture is that each buffer can contain the whole double words DWs thus leaving free the sense amplifier to read in another memory location.

The presence of the modified JTAG cell 500 is particular important as output of the sense amplifiers since allows:
a. Using the boundary scan as method to check the interconnection between the SoC 10 and the Flash Array component 1;
b. Implement the Direct Memory Access connecting directly the sense amplifier with the controller;
c. It allows to leave the sense amplifier to prepare the second 256 bit wide page plus the address plus the ECC and written close to the page.

Another advantage is given by the possibility to adopt a boundary-scan test architecture including modified JTAG cells 500 thus obtaining a new and peculiar boundary-scan test architecture like the one shown in the schematic view of FIG. 6. This is a further advantage since for this test only one output driven is needed and this is obtained using the signal TCK and the data stored in the cells. The scan chain test requires the SoC 10 to test the output of the scan chain.

As it is known in this specific technical field, boundary scan is a family of test methodologies aiming at resolving many test problems: from chip level to system level, from logic cores to interconnects between cores, and from digital circuits to analog or mixed-mode circuits.

The boundary-scan test architecture 600 provides a means to test interconnections between the integrated circuits 1 and 10 on a board without using physical test probes. It adds a boundary-scan cell 500 that includes a multiplexer and latches, to each pin or pad on the device.

In other words, each primary input signal and primary output signal of a complex semiconductor device like the memory component 1 or the host device 10 is supplemented with a multi-purpose memory element called a boundary-scan cell that, altogether, form a serial shift register 650 around the boundary of the device.

Originally, those boundary-scan cells have been introduced as a means of applying tests to individual semiconductor devices. The use of boundary-scan cells to test the presence, orientation, and bonding of devices in place on a circuit board was the original motivation for inclusion in a semiconductor device.

According to the present disclosure the boundary-scan cells 500 are also used to test the interconnections between integrated circuits that work together such as the System-on-Chip 10 with the associated memory component 1, as is the case of the present disclosure.

The collection of boundary-scan cells is configured into a parallel-in or parallel-out shift register and the boundary-scan path is independent of the function of the hosting device. The required digital logic is contained inside the boundary-scan register. Obviously, an external JTAG FSM interacts with the cells, i.e. shiftDR, shiftlR, UpdateDR, etc. are driven by the JTAG logic 300.

To summarize very briefly the functioning of a boundary-scan cell it may be said that each cell 500 is structured for capturing data on its parallel input PI; updating data onto its parallel output PO; serially scanning data from its serial output SO to its neighbor's serial input SI. Moreover, each cell behaves transparently, in the sense that PI passes to PO.

FIG. 6 shows a schematic view of a standard structure architecture using boundary-scan cells configured according to the IEEE standard No. 1149.1. However, according to the present disclosure, the boundary-scan cells used in the architecture 600 are the modified JTAG cells 500 previously disclosed.

A JTAG interface is a special interface added to a chip. According to present embodiments, two, four, or five pins are added allowing to expand the JTAG according to the need of the present implementation.

The connector pins are: TDI (Test Data In); TDO (Test Data Out); TCK (Test Clock); TMS (Test Mode Select) and an optional TRST (Test Reset).

The TRST pin is an optional active-low reset to the test logic, usually asynchronous, but sometimes synchronous, depending on the chip. If the pin is not available, the test logic can be reset by switching to the reset state synchronously, using TCK and TMS. Note that resetting test logic doesn't necessarily imply resetting anything else. There are generally some processor-specific JTAG operations which can reset all or part of the chip being debugged.

Since only one data line is available, the protocol is serial. The clock input is at the TCK pin. One bit of data is transferred in from TDI, and out to TDO at each TCK rising clock edge. Different instructions can be loaded. Instructions for typical ICs might read the chip ID, sample input pins, drive (or float) output pins, manipulate chip functions, or bypass (pipe TDI to TDO to logically shorten chains of multiple chips).

As with any clocked signal, data presented to TDI must be valid for some chip-specific Setup time before and Hold time after the relevant (here, rising) clock edge. TDO data is valid for some chip-specific time after the falling edge of TCK.

FIG. 6 shows a set of four dedicated test pins—Test Data In (TDI), Test Mode Select (TMS), Test Clock (TCK), Test Data Out (TDO)—and one optional test pin Test Reset (TRST).

These pins are collectively referred as a Test Access Port (TAP). However, the architecture 600 includes a finite-state machine, named TAP controller 670, with receives as inputs three signals: TCK, TMS, and TRST. The

TAP controller 670 is a 16-state final state machine FSM that controls each step of the operations of boundary scan architecture 600. Each instruction to be carried out by the boundary scan architecture 600 is stored in the Instruction Register 620.

FIG. 6 shows a plurality of boundary-scan cells 500 on the device primary input and primary output pins. The cells 500 are connected internally to form a serial boundary-scan register 650. In other words, the modified JTAG cells 500 are used as building blocks of the boundary scan architecture 600.

Data can also be shifted around the boundary-scan shift register 650 in serial mode, starting from a dedicated device input pin called “Test Data In” (TDI) and terminating at a dedicated device output pin called “Test Data Out” (TDO) at the output of a multiplexer 660.

The test clock, TCK, is TCK is selectively sent to each register depending on the TAP state and to the register selection; the fed of the TCK signal is performed via a dedicated device input pin and the mode of operation is controlled by a dedicated “Test Mode Select” (TMS) serial control signal.

The Instruction Register (IR) 620 includes n-bit (with n≥2) and is implemented for holding each current instruction.

In line with the IEEE 1149 standard the architecture is completed by a 1-bit bypass register 640 (Bypass); an optional 32-bit Identification Register 630 (Ident), capable of being loaded with a permanent device identification code.

At any time, only one register can be connected from TDI to TDO (e.g., IR, Bypass, Boundary-scan, Ident, or even some appropriate register internal to the core logic). The selected register is identified by the decoded output of the IR. Certain instructions are mandatory, such as Extest (boundary-scan register selected), whereas others are optional, such as the Idcode instruction (Ident register selected).

A parallel load operation is called a “capture” operation and causes signal values on device input pins to be loaded into input cells and signal values passing from the core logic to device output pins to be loaded into output cells.

A parallel unload operation is called an “update” operation and causes signal values already present in the output scan cells to be passed out through the device output pins. Moreover, a PAUSE instruction permits to hold the data in the register even if it is not completed.

Depending on the nature of the input scan cells, signal values already present in the input scan cells will be passed into the core logic.

Now, in one embodiment of the present disclosure the boundary-scan architecture 600 is completed with a further or additional register 780 that is specifically provided to manage the memory component 1. This additional register 780 is also definable by the user. This expansion is allowed by the IEEE 1532 standard.

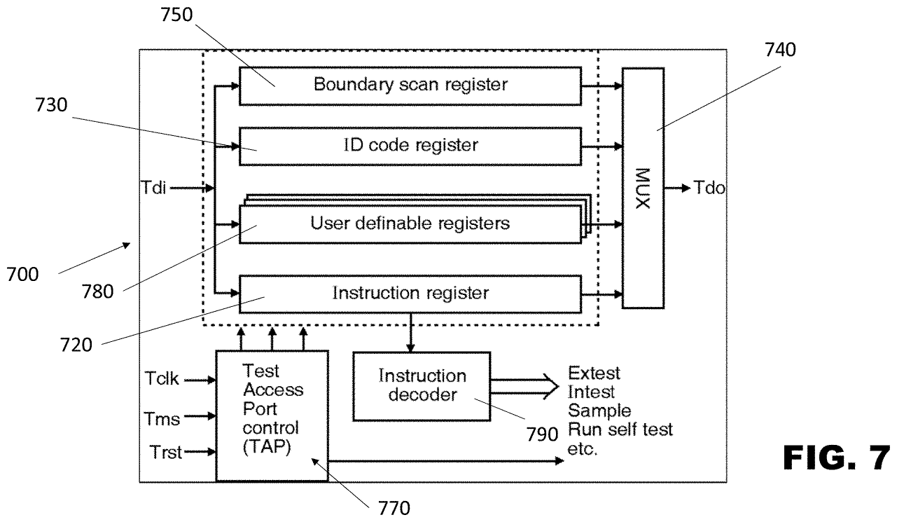

FIG. 7 shows in greater details the composition of the registers incorporated into the boundary-scan architecture 600 of the present disclosure. In this FIG. 7 the boundary-scan shift register 750 is coupled to the TDI pin in serial mode and provides an output toward the TDO output pin via the multiplexer 760.

The test clock, TCK, is fed in via yet another dedicated device input pin and the mode of operation is controlled by a dedicated “Test Mode Select” (TMS) serial control signal both applied to the TAP controller 770.

The various control signals associated with the instruction are then provided by a decoder 790.

The Instruction Register (IR) 720 includes n-bit (with n≥2) and is implemented for holding each current instruction. The architecture includes a 1-bit bypass register (not shown in FIG. 7) and the Identification Register 730.

The additional register 780 is used as shift data register for allowing the interaction with the core of the host device in the writing and/or reading phases of the memory component. However, the user definable register can even be different. Depending on the command loaded in the IR, different register can be combined. For instance, to program the memory it may be necessary to dispose of at least: a data register with size the min page to be programmed in the memory array, a data address that contains which address can be loaded and, optionally, a mask register to avoid touching a portion of the data, among other things.

Now, the command user interface represented by the TAP controller 670 or 770 is based on the IEEE1149 and IEEE1532 standards, that implement a low signal count interface, i.e. TMS, TCK, TDI, TDO, TRST (Optional) with capability to modify the internal content of the associated memory sub array 200.

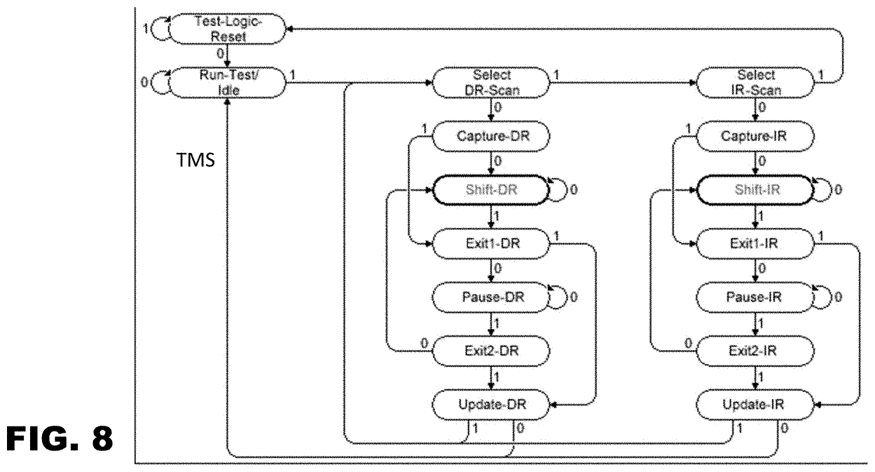

As shown in FIG. 8, the standard IEEE1149.1 is based on a TAP finite state machine that includes sixteen states, and two of them, i.e. shift instruction register (ShiftlR) and shift data register (ShiftDR), allows the interaction with the system in write and/or read.

More particularly, the shift data register ShiftDR reports a state where the TDI is connected with a register. In that state the register content is transferred in and/or out of the device.

Similarly, the shift instruction register ShiftlR also reports a state where the TDI is connected with a register. Instruction are loaded in that state.

Due to the requirement of having multiple core inside the host device 10, the internal register 780 of the JTAG interface must be able to support up to address and data registers. In particular, the generation of four address registers (one from each sub-array 200) is provided to be filled with a different address for each sub array 200 and triggering four different data out for the read register [0:3], per sub-array section. The communication to the SoC happens connecting the selected Read Register, i.e. the output named POUT [127:0], directly to input of the channel of the host device or SoC 10.

This mechanism allows to pre-load the data for the controller, reducing the latency time to a very low value.

For completeness sake, it should be noted that the JTAG state machine can reset, access an instruction register, or access data selected by the instruction register.

JTAG platforms often add signals to the handful defined by the IEEE 1149.1 specification. A System Reset (SRST) signal is quite common, letting debuggers reset the whole system, not just the parts with JTAG support. Sometimes there are event signals used to trigger activity by the host or by the device being monitored through JTAG; or, perhaps, additional control lines.

In JTAG, devices expose one or more test access ports (TAPs).

To use JTAG, a host is connected to the target's JTAG signals (TMS, TCK, TDI, TDO, etc.) through some kind of JTAG adapter, which may need to handle issues like level shifting and galvanic isolation. The adapter connects to the host using some interface such as USB, PCI, Ethernet, and so forth

The host device 10 communicates with the TAPs by manipulating TMS in conjunction with TCK, and reading results through TDO (which is the only standard host-side input). In this case the signal TDI is used only to load register data. The signals moving the TAP are: TCK, TMS and TRST (if implemented). TMS/TDI/TCK output transitions create the basic JTAG communication primitive on which higher layer protocols build:

State switching: wherein all the TAPs are moving accordingly because the TMS is connected at the same time to all the JTAG compliant devices, if they are present in the board. The state changes on TCK transitions.

As shown in FIG. 8, this JTAG state machine is part of the JTAG specification and includes sixteen states. There are six “stable states” where keeping TMS stable prevents the state from changing. In all other states, TCK always changes that state. In addition, asserting the signal TRST forces entry to one of those stable states (Test_Logic_Reset), bringing to the default value all the content of the registers. Their content is no longer valid and it should be reloaded. The stable state is thus reached in a slightly quicker way than the alternative of holding TMS high and cycling TCK five times.

Shifting phase: wherein most parts of the JTAG state machine support two stable states used to transfer data. Each TAP has an instruction register (IR) and a data register (DR). The size of those registers varies between TAPs, and those registers are combined through TDI and TDO to form a large shift register. (The size of the DR is a function of the value in that TAP's current IR, and possibly of the value specified by a SCAN_N instruction.) Usually there is a optional register to define the size of the data registers. The IR is checked using the standard since the low significant bits are loaded with 1 and 0. This allows to count the number of JTAG devices in the network and having knowledge of the size of each TAP IR.

There are three operations defined on that shift register:

Capturing a temporary value.

Entry to the Shift_IR stable state goes via the Capture_IR state, loading the shift register with a partially fixed value (not the current instruction)

Entry to the Shift_DR stable state goes via the Capture_DR state, loading the value of the Data Register specified by the TAP's current IR.

Shifting that value bit-by-bit, in either the Shift_IR or Shift_DR stable state; TCK transitions shift the shift register one bit, from TDI towards TDO, exactly like a SPI mode 1 data transfer through a daisy chain of devices (with TMS=0 acting like the chip select signal, TDI as MOSI, etc.).

Updating IR or DR from the temporary value shifted in, on transition through the Update_IR or Update_DR state. Note that it is not possible to read (capture) a register without writing (updating) it, and vice versa. A common idiom adds flag bits to say whether the update should have side effects, or whether the hardware is ready to execute such side effects.

The PAUSE state is also part of the standard in each side of the shift branch.

Running state: wherein one stable state is called Run_Test/Idle. The distinction is TAP-specific. Clocking TCK in the Idle state has no particular side effects, but clocking it in the Run_Test state may change system state. For example, some cores support a debugging mode where TCK cycles in the Run_Test state drive the instruction pipeline.

So, at a basic level, using JTAG involves reading and writing instructions and their associated data registers; and sometimes involves running a number of test cycles. Behind those registers is hardware that is not specified by JTAG, and which has its own states that is affected by JTAG activities.

JTAG Finite State Machine is triggered at the rising edge of the TCK, the clock signal and provides output at the falling edge. This allows to use the bypass register and not losing clock cycles in the chain.

The TMS signal is checked and its value triggers the state transition.

The ShiftDR and ShiftIR state are addressing I0 registers and the TDI signal is used to serial insert data inside the selected register

The IR Register is used to select the specific data register and/or the instruction to be used.

When the state machine is in run-test/idle, the IR register is checked for a command and it is executed, using the data of eventual service registers, i.e. a program command can use the data register and the address register to decide what and where the data must be stored.

JTAG boundary scan technology provides access to many logic signals of a complex integrated circuit, including the device pins. The signals are represented in the boundary scan register (BSR) accessible via the TAP. This permits testing as well as controlling the states of the signals for testing and debugging. Therefore, both software and hardware (manufacturing) faults may be located and an operating device may be monitored.

The present disclosure obtains many advantages reported hereinafter not in order of importance. The solution previously disclosed reduces the cost of the silicon for the memory component and improve the overall quality and reliability issues for the whole apparatus including the host device and memory component.

The apparatus of the present disclosure offers a good option for realizing Real Time Operative Systems (RTOS), especially in the Automotive segment, providing a low initial latency in the first access of the memory component and, at the same time, a throughput of Gigabits per seconds. More specifically the architecture of the present disclosure reaches a throughput of at least 9.6 Gigabit per second (9.6 Gbps).

Moreover, the memory architecture previously disclosed provides for a very high quality and an error rate in the range of less than 1 part per million.

It is also offered an in-line ECC mechanism and/or similar methods to spare data lines containing ECC syndrome, even if the possible correction is left to the host or SoC device, thus working independently.

Finally, the disclosed architecture allows adopting an aggressive lithography node in the host device and the latest flash memory technology in the memory component, thus decoupling of the technology so to have the best of the two in place.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure.

It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

1-25. (canceled)

26. An apparatus comprising:
a memory component having an independent structure and including an array of memory cells with associated decoding and sensing circuitry and a memory controller;
a host device including multiple cores and coupled to the memory component through at least a communication channel for each corresponding core;
a control and JTAG interface in the array of memory cells; and
at least an additional register in the control and JTAG interface for handing data, address, and control signals provided by the host device to be delivered to a decoding circuitry and to the memory controller to perform modify operations.

27. The apparatus of claim 26, wherein the array of memory cells includes a plurality of sub arrays and the additional register in the control and JTAG interface supports data and address registers of each sub array of memory cells.

28. The apparatus of claim 26, wherein the memory component includes a plurality of sub arrays with a read interface including sense amplifiers and a data buffer and wherein an internal register of the JTAG interface is structured to generate at least four address registers filled with corresponding different addresses and triggering at least four different data from the read interface of each sub-array.

29. The apparatus of claim 28, wherein the data buffer includes a plurality of modified JTAG cells coupled to corresponding outputs of the sense amplifiers.

30. The apparatus of claim 28, wherein each sense amplifier is connected directly to a modified JTAG cell to integrate a JTAG structure and the sense amplifiers in a single circuit portion.

31. The apparatus of claim 29, wherein the plurality of modified JTAG cells are further used as building blocks of a boundary-scan shift register in a boundary scan architecture.

32. The apparatus of claim 29, wherein the the plurality of modified JTAG cells include a boundary scan cell comprising an input multiplexer and an output multiplexer and at least a further pair of latches between the input multiplexer and the output multiplexer.

33. The apparatus of claim 28, wherein the memory component includes at least four sub arrays and each sub array is independently addressable inside the memory component.

34. The apparatus of claim 28, wherein a scan-chain is formed by serially interconnecting the JTAG cells of the data buffer.

35. The apparatus of claim 32, wherein the further pair of latches are connected in a pipeline between a parallel input and a parallel output of the modified JTAG cell.

36. The apparatus of claim 26, wherein each core is coupled to a communication channel for independently receiving and transferring data to the memory component connecting directly a selected read register to an input of a corresponding channel of the host device.

37. A memory device, comprising:
at least a memory array with associated decoding and sensing circuitry;
a memory controller;
a control and JTAG interface in the at least a memory array; and
at least an additional register in the control and JTAG interface for handing data, address and control signals provided from a communication channel connecting the memory device to a host device.

38. The memory device of claim 37, wherein the control and JTAG interface includes a JTAG state machine structured to reset or access an instruction register as well as to access data selected by the instruction register.

39. The memory device of claim 37, wherein the control and JTAG interface is configured to:
receive, as inputs, standard JTAG signals including TMS, TCK, and TDI signals as well as data from a memory page; and
produce, as output, data, address, and control signals that are transferred to a memory address decoder and to the memory controller to perform modify operations.

40. The non-volatile memory device of claim 37, wherein the non-volatile memory device memory is structured to be in communication with a plurality of cores of a host device through corresponding communication channels and wherein a selected read register of the memory device is connected directly to an input of a corresponding channel of the host device for independently receiving and transferring data.

41. The non-volatile memory device of claim, 37 wherein the memory device is a non-volatile memory device, and wherein the memory array is a NAND Flash memory array.

42. A method, comprising:
handling input data, address signals, and JTAG signals through a control and JTAG interface of a memory component to deliver input signals to decoding circuitry of the memory component and a memory controller to perform modify operations.

43. The method of claim 42, wherein the method includes pre-loading input data for the memory controller.

44. The method of claim 42, wherein an array of memory cells includes a plurality of sub arrays and an additional register in the control and the JTAG interface supports data and address registers of each sub array of memory cells.

45. The method of claim 44, wherein the additional register is structured to support generating at least an address register for each corresponding sub-array and for triggering different data output for a corresponding read register of each sub-array putting directly in communication the corresponding read register with the input data of a corresponding channel of a host device coupled to the memory component through at least a communication channel for each of multiple cores of the host device.
